(19) United States
(12) Patent Application Publication
(10) Pub. No.: US 2026/0170194 A1
(43) Pub. Date: Jun. 18, 2026

(54) SPOT-WELDED JOINT FATIGUE PROPERTY AND ANALYSIS METHOD WITH AREA CONTACT MODEL

(71) Applicant: FCA US LLC, Auburn Hills, MI (US)

(72) Inventors: Mingchao Guo, Auburn Hills, MI (US); Congyue Wang, Auburn Hills, MI (US)

(21) Appl. No.: 18/978,457

(22) Filed: Dec. 12, 2024

(51) Int. Cl. G06F 30/17

(52) U.S. Cl. CPC G06F 30/17

(57) ABSTRACT

A method of conducting fatigue analysis of a plurality of spot welds of a vehicle that may include selecting a target fatigue life for the plurality of spot welds, testing each of the spot welds using a mesh independent linear computer aided engineering (CAE) model, determining a number of the spot welds that did not reach the target fatigue life, and testing the number of spot welds that did not reach the target fatigue life using a mesh dependent linear CAE model.

### FIELD

The present disclosure relates to a spot-welded joint fatigue property and analysis method with an area contact model.

### BACKGROUND

This section provides background information related to the present disclosure which is not necessarily prior art.

A typical vehicle body can contain between 3000 to 5000 spot welds. This type of weld is very common because spot welding can be automated, which decreases the manufacturing time associated with manufacturing a car body having so many of these welds. As development of vehicle bodies has advanced over the last twenty to thirty years, however, weight reduction has become essential to improve fuel consumption, which has resulted in thinner sheet metal being used for the vehicle body. The thinner sheet metal may lead to greater stresses being experienced by the vehicle body, which can in turn result in the spot welds being exposed to greater stresses that may cause the weld to fail.

In view of the above, linear computer aided engineering (CAE) tools have been developed to determine the fatigue life of spot welds. An example linear CAE tool is a CBAR element. Since these tools use a linear approach, however, non-linear characteristics of the weld spots such as plasticity of the weld that may occur during low amplitude cycles and a stiffness reduction of the weld that may occur due to crack propagation at high amplitude cycles cannot be determined. Linear CAE tools, therefore, may determine that the spot-welded joints may experience higher reaction forces and moments in comparison to what the spot-welded joints experience in a real vehicle body structure. Put another way, linear CAE tools may predict a fatigue life that is too conservative in comparison to what a real vehicle body structure will experience.

Another drawback to using a linear CAE approach is that when a spot-welded joint is simulated with a CBAR element it is connected to the adjacent shell elements with a single node at each end. Put another way, simulating a spot-welded joint with a CBAR element joint modeling approach is mesh dependent, which requires significant additional modeling time. In addition, a single node connection provides lower joint stiffness in comparison to what is experienced by an actual joint. The lower stiffness may result in lower frequency of a body structure, and correspondingly may affect accuracy of the linear CAE prediction of spot-welded joint fatigue life on the vehicle body structure.

Accordingly, it is desirable to develop a spot-welded joint fatigue property and analysis method that can consider non-linear characteristics of the weld such as plasticity of the weld that may occur during low amplitude cycles and a stiffness reduction of the weld that may occur due to crack propagation at high amplitude cycles, and avoids significant additional modeling time.

### SUMMARY

This section provides a general summary of the disclosure, and is not a comprehensive disclosure of its full scope or all of its features.

According to a first aspect of the present disclosure, there is provided a method for determining fatigue life of a plurality of spot welds in a vehicle. The method may include subjecting a first plurality of coupons that represent welded joints in the vehicle to a plurality of low amplitude cycles to determine a first force (F_{t,n}) associated with a first non-linear characteristic of the spot welds; subjecting a second plurality of coupons that represent welded joints in the vehicle to a plurality of high amplitude cycles to determine a second force (Fₜ) associated with a second non-linear characteristic of the spot welds; inputting the first force and the second force into a linear computer aided engineering (CAE) model to generate a third force (F_{e,n}) associated with the first non-linear characteristic of the spot welds and a fourth force (Fₑ) associated with the second non-linear characteristic of the spots welds; determining a first force factor ((F_{e,n})/(F_{t,n})) associated with the first non-linear characteristic of the spot welds and determining a second force factor ((Fₑ)/(Fₜ)) associated with the second non-linear characteristic of the spot welds; inputting the first and second force factors into the CAE model to determine internal forces and moments experienced by spot welds; calculating stresses experienced by the spot welds using the internal forces and moments; and generating a fatigue life (S-N) curve using the calculated stresses.

According to the first aspect, the CAE model is an Area Contact Model 2 (ACM2).

According to the first aspect, the ACM2 model is mesh dependent.

According to the first aspect, the coupons include lap shear joints and coach peel joints.

According to the first aspect, the first non-linear characteristics is a plasticity of the spot welds at low amplitude cycles.

According to the first aspect, the second non-linear characteristic is a stiffness reduction of the spot welds that can occur due to crack propagation at high amplitude cycles.

According to a second aspect of the present disclosure, there is provided a method of conducting fatigue analysis of a plurality of spot welds of a vehicle. The method may include selecting a target fatigue life for the plurality of spot welds; testing each of the spot welds using a mesh independent linear computer aided engineering (CAE) model; determining a number of the spot welds that did not reach the target fatigue life; and testing the number of spot welds that did not reach the target fatigue life using a mesh dependent linear CAE model.

According to the second aspect, the mesh independent linear CAE model is a mesh independent Area Contact Model 2 (ACM2).

According to the second aspect, the mesh dependent linear CAE model is a mesh dependent Area Contact Model 2 (ACM2).

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 illustrates an example vehicle that may have a plurality of spot welds to connect portions of the vehicle body to each other;

FIGS. 2A and 2B illustrate example joints between the portions of the vehicle body that are connected by spot-welding;

FIG. 3 is a graph illustrating an S-N curve that was generated according to a method of the present disclosure;

FIG. 4 is a flow chart illustrating a method according to a principle of the present disclosure that can be used to generate the S-N curve illustrated in FIG. 3;

FIG. 5 is a graph illustrating how a first force factor α associated with a plasticity of a weld spot that occurs at low amplitude cycles is determined;

FIG. 6 is a graph illustrating how a second force factor associated with a stiffness reduction of the weld that may occur due to crack propagation at high amplitude cycles is determined;

FIG. 7 is a table listing various force factors that were determined according to a method of the present disclosure;

FIGS. 8A and 8B illustrate an example mesh independent ACM2 model and a mesh dependent ACM2 model, respectively, that can be used to determine stresses experienced by a spot weld; and

FIG. 9 is a flow chart illustrating another method according to a principle of the present disclosure.

Corresponding reference numerals indicate corresponding parts throughout the several views of the drawings.

### DETAILED DESCRIPTION

Example embodiments will now be described more fully with reference to the accompanying drawings. The example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

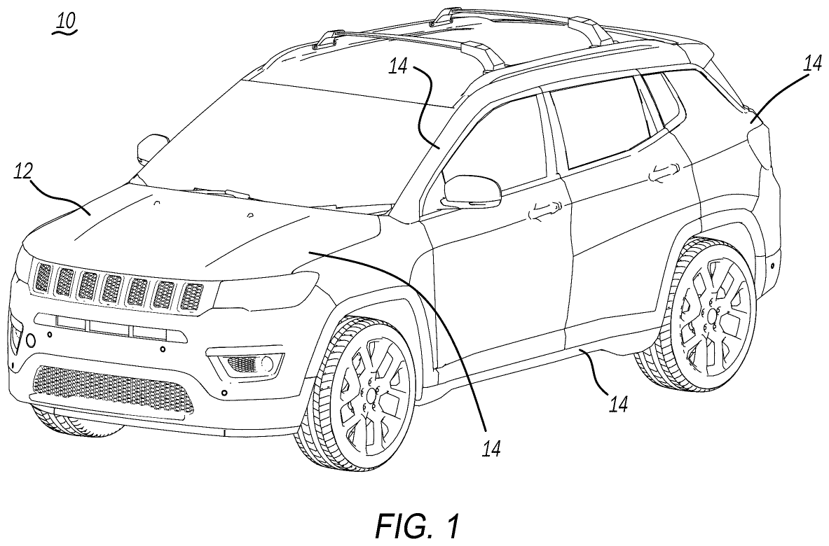

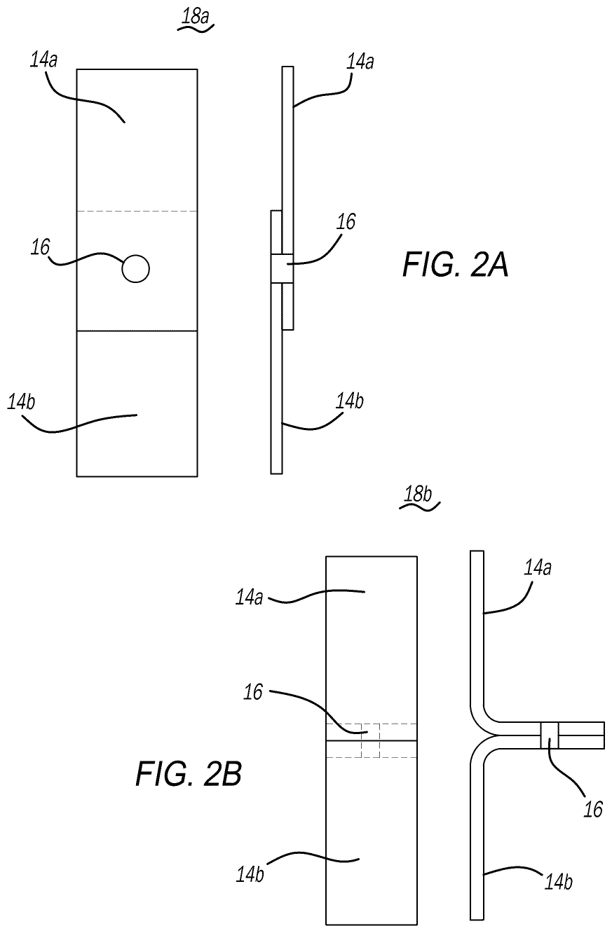

FIG. 1 illustrates an example vehicle 10 that includes a vehicle body 12 that is composed of multiple panels 14 that may be joined together by spot welding. FIGS. 2A and 2B show different examples of how the panels 14 can be connected to each other using a spot weld 16. In this regard, FIG. 2A illustrates a lapped joint 18a where a first panel 14a overlaps a second panel 14b and secured with a spot weld 16, and FIG. 2B illustrates another lapped joint 18b where the first and second panels 14a, 14b are abutted against each other and secured with a spot weld 16. Each panel 14a, 14b may be formed of a rigid metal material such as, for example, an advanced high-strength steel. The material used for each panel 14a, 14b can be the same, or the material used for each panel 14a, 14b can be different. For example, first panel 14a can be formed of a first advanced high-strength steel and second panel 14b can be formed of a second and different advanced high-strength steel. In addition, it should be understood that a thickness of panels 14a and 14b can be the same, or a thickness of panel 14a can be greater or lesser than that of panel 14b.

FIGS. 2A and 2B also illustrate the configurations that may be used to physically test a strength of the spot welds 16, with FIG. 2A being subjected to a so-called “lap shear” test and FIG. 2B being subjected to a so-called “coach peel” test. To test the different joints 18a and 18b, the joints 18a, 18b may be subjected to constant load amplitudes at frequencies that range between 5 Hz to 30 Hz, and the number of cycles determined before the spot welds 16 fail. It goes without saying that testing of the spot welds 16 in each joint 18a, 18b can be time and labor intensive, and can be impractical from the standpoint that there can be between 3000 to 5000 spot welds 16 in the example vehicle 10 illustrated in FIG. 1.

As noted above, linear computer aided engineering (CAE) tools have been developed to determine the fatigue life of spot welds. As also noted above, however, non-linear characteristics of the weld spots such as plasticity of the weld that may occur during low amplitude cycles and a stiffness reduction of the weld that may occur due to crack propagation at high amplitude cycles cannot be determined using existing CAE tools. In addition, existing CAE tools still require significant modeling time that can be impractical due to the large number of spot welds 16 in a vehicle 10 such as that illustrated in FIG. 1.

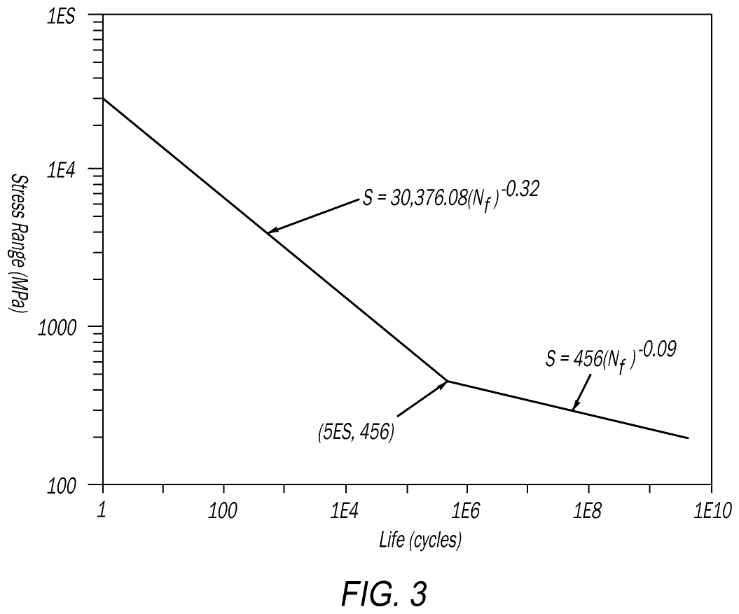

With the above in mind, the present disclosure provides a method of generating an S-N curve that depicts the relationship between stress applied to the spot weld 16 (S) and the number of cycles (N) before the spot weld 16 fails, which considers non-linear characteristics of the spot welds 16 such as plasticity of the weld that may occur during low amplitude cycles and a stiffness reduction of the weld that may occur due to crack propagation at high amplitude cycles. The S-N curve generated by the developed method is illustrated in FIG. 3.

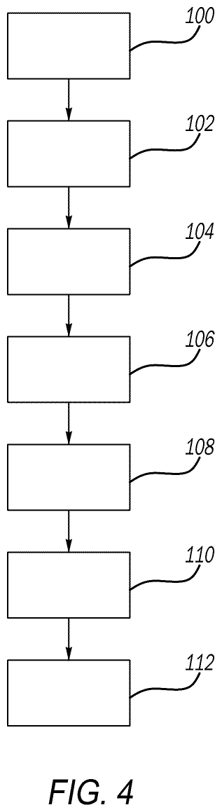

The S-N curve illustrated in FIG. 3 was generated by the method illustrated in FIG. 4. In a first step (step 100), actual sample data of the joints 18a and 18b illustrated in FIGS. 2A and 2B was generated. Specifically, the joints 18a and 18b were subjected to testing to determine a force (F_{t,n}), a displacement (d_{t,n}), and number of cycles (n) that were necessary to cause the joints 18a and 18b to fail during a low cycle fatigue regime to take plasticity of the weld spot 16 into consideration. In addition, the joints 18a and 18b were subjected to testing to determine a force (Fₜ), a displacement (dₜ₂), and number of cycles (n) during a high cycle fatigue regime to take stiffness reduction due to crack propagation of the weld spot 16 into consideration. A few hundred (e.g., 200) “coupons” having the structures shown in FIGS. 2A and 2B were used to generate this data.

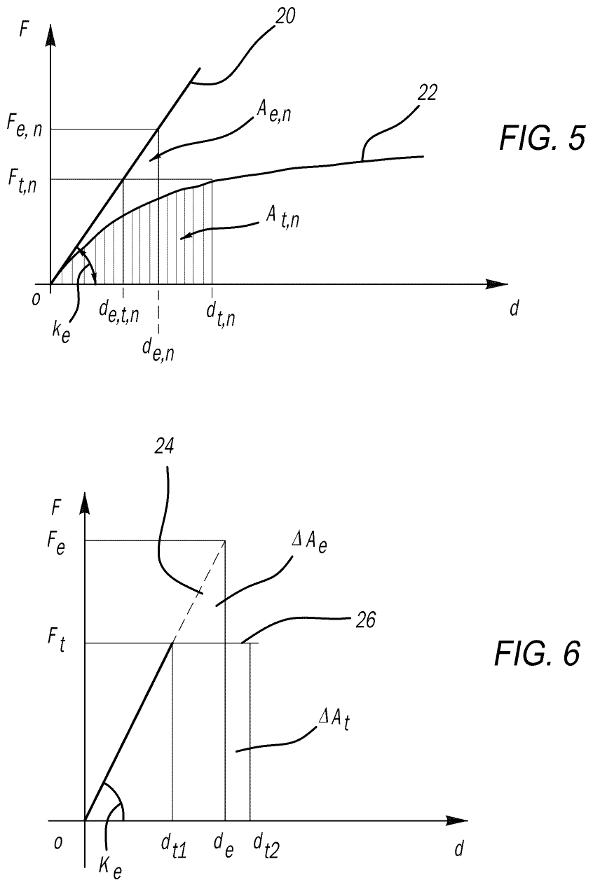

Next, using the data obtained in step 100, the curves 22 (FIG. 5) and 26 (FIG. 6) were generated (step 102). The curves 22 and 26 represent non-linear characteristics of the weld spots 16 such as a plasticity of the weld spot 16 during the low cycle fatigue regime (FIG. 5) and a stiffness reduction due to crack propagation (FIG. 6), respectively.

Because the data associated with curves 22 and 26 are non-linear, the data (e.g., F_{t,n}, d_{t,n}, F_{t,n}, and dₜ₂) associated with these curves cannot be input into a linear CAE model such as a mesh dependent “Area Contact Model 2” (hereinafter “ACM2). Thus, in order to generate linear data from non-linear data represented by curves 22 and 26 that can be input into the mesh dependent ACM2 model, the method uses the non-linear data associated with curves 22 and 26 to generate data associated with a force (F_{e,n}), displacement (d_{e,n}), and number of cycles (n) (curve 20 in FIG. 5), and a force (Fₑ), displacement (dₑ), and number of cycles (n) (curve 24 in FIG. 6) (step 104). Specifically, in step 104 of the method shown in FIG. 4, the “equal energy rule” is used to determine F_{e,n}, d_{e,n}, Fₑ, and dₑ. The calculations used according to the “equal energy rule” to determine F_{e,n}, d_{e,n}, Fₑ, and dₑ shown in FIGS. 5 and 6 are as follows.

To determine F_{e,n} and d_{e,n} in FIG. 5, the equal energy rule is followed:

$${A}_{e , n} = {A}_{t , n} \qquad ( 1 )$$

$${A}_{t , n} = {\sum }_{1}^{n} ( {F}_{t , i} * Δ {d}_{i} ) \qquad ( 2 )$$

$${A}_{e , n} = 1 / 2 * {F}_{e , n} * {d}_{e , n} = 1 / 2 * {F}_{e , n}^{2} / {K}_{e} \qquad ( 3 )$$

$${F}_{e , n} = \sqrt{( 2 * {K}_{e} * {A}_{t , n} )} \qquad ( 4 )$$

$$α = {F}_{e , n} / {F}_{t , n} \qquad ( 5 )$$

where:
A_{t,n}=energy of test sample under level n loading; Fᵢ=force of test sample under level i loading (i=1 to n); Δdᵢ=displacement interval; A_{e,n}=energy of linear sample model associated to level n loading; F_{e,n}=force in the linear sample model associated to level n loading; Kₑ=stiffness of the linear sample model; d_{e,t,n}=displacement in the linear sample model associated to test load F_{t,n}; d_{e,n}=displacement in the linear sample model associated to level n loading; d_{t,n}=displacement of the test sample under level n loading; and α=force factor.

To determine Fₑ and dₑ in FIG. 6, the equal energy rule is also followed:

$$Δ {A}_{e} = Δ {A}_{t} \qquad ( 6 )$$

$$1 / 2 ( {d}_{e} - {d}_{t 1} ) ( {F}_{e} - {F}_{t} ) = ( {d}_{t 2} - {d}_{e} ) {F}_{t} \\ If α = \frac{{F}_{e}}{{F}_{t}} = 1.4 \qquad ( 7 )$$

$${d}_{e} = 1.4 {d}_{t 1} \qquad ( 8 )$$

$$1 / 2 ( 1.4 {d}_{t 1} - {d}_{t 1} ) ( 1.4 {F}_{t} - {F}_{t} ) = ( {d}_{t 2} - {d}_{e} ) {F}_{t} \qquad ( 9 )$$

$${d}_{t 2} = 1.88 {d}_{t 1} \qquad ( 10 )$$

In sample testing data, the average dₜ₂ is about 2.0dₜ₁; therefore α=1.4.

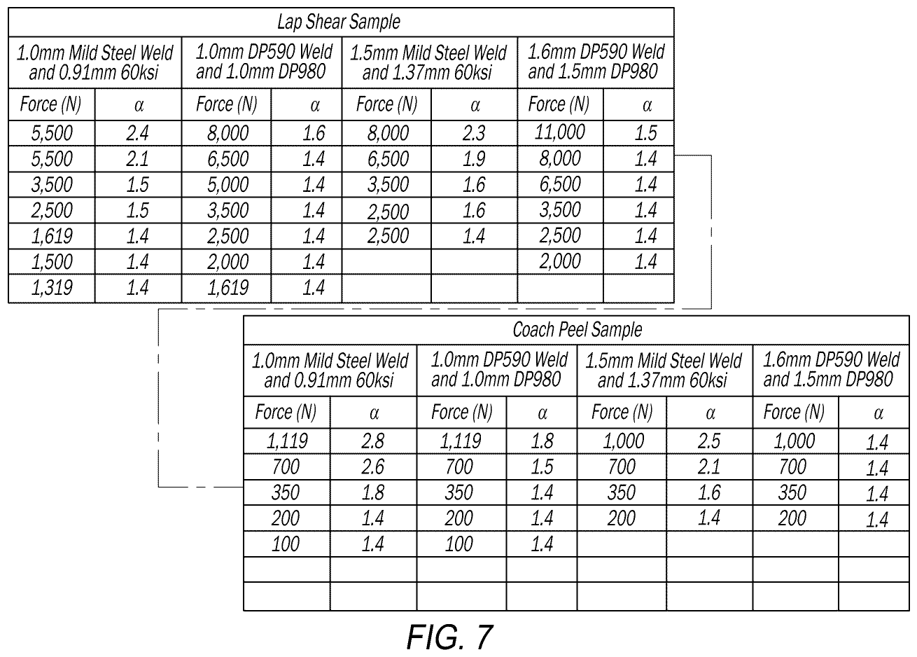

Next, in step 106, “force factors” (α in the above calculations) are determined to normalize the differences between the curves 20 and 22 and the curves 24 and 26. A force factor ((F_{e,n})/(F_{t,n})) is associated with curves 20 and 22, and a force factor ((Fₑ)/(Fₜ)) is associated with curves 24 and 26. The force factors determined in step 106 are listed in FIG. 7.

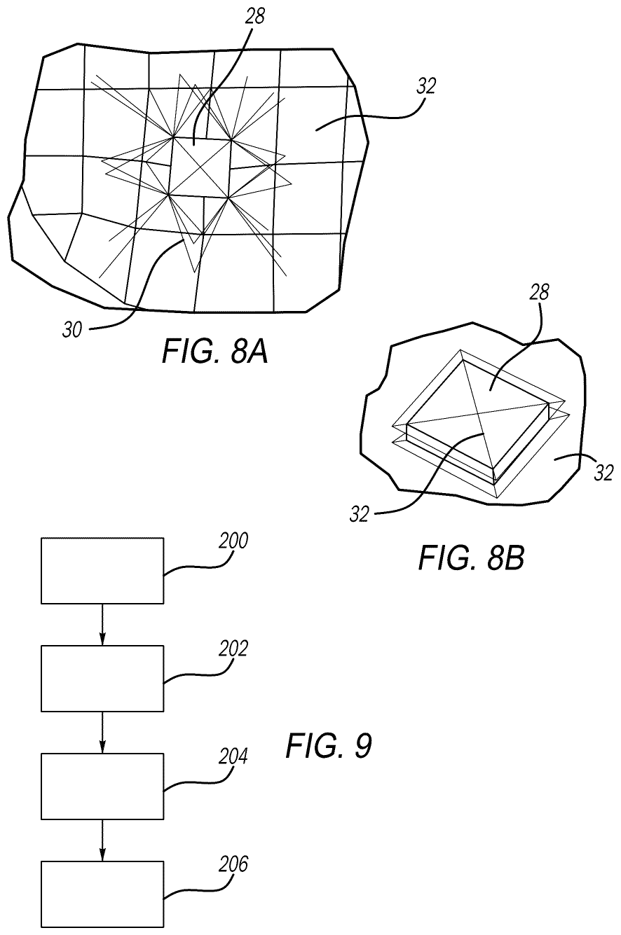

Next, in step 108, the force factors and other data (e.g., material of the panels 14a, 14b, thicknesses of the panels 14a, 14, the type of joint (FIG. 2A or 2B) associated with various virtual “coupons” like those shown in FIGS. 2A and 2B are input into the mesh dependent ACM2 model to determine internal forces and moments experienced by the virtual “nugget” 28 (FIGS. 8A and 8B) that represents the weld spot 16.

Next, in step 110, the internal forces and moments determined using the ACM2 model can then be used to calculate the structural stresses of the joints 18a and 18b according the method set forth by Rupp et al (“Computer Aided Dimensioning of Spot-Welded Automotive Structures,” SAE Technical Paper Series, Vol. 950711 (1995), which is incorporated herein by reference in its entirety. After the stresses are determined, the number of cycles to failure can be determined and the S-N curve illustrated in FIG. 3 is generated (step 112) that can be used to predict the fatigue life of the spot welds 16 in the vehicle 10.

In another aspect of the present disclosure (FIG. 9), fatigue analysis of the spot welds 16 that connect the panels 14 of the vehicle body 12 can be conducted in a faster and more efficient manner. First, a target fatigue life is selected for each of the spot welds 16 of the vehicle body 12 (step 200). For example, a fatigue life of 10000 cycles can be used. Then each of the spot welds 16 of the vehicle body 12 can be tested using a linear CAE tool such as mesh independent ACM2 (step 202). An example of mesh independent ACM2 is illustrated in FIG. 8A. An example of mesh dependent ACM2 is illustrated in FIG. 8B. The modelling time associated with mesh independent ACM2 is significantly less than mesh dependent ACM2. In this regard, the connections (e.g., mesh 30) between the shell elements 32 (which virtually represent the panels 14a, 14b) and the nugget 28 are randomly generated automatically using the ACM2 tool, all of the joints 18a, 18b in one body structure (e.g., vehicle 10) can be generated simultaneously automatically, and no mesh 30 quality check or mesh 30 modification is needed. It should be noted, however, that the variance in fatigue life associated with mesh independent ACM2 can be up to ten times the variance in fatigue life associated with mesh dependent ACM2 because the forces and moments of the nugget 28 vary depending on the connection patterns between the nugget 28, mesh 30, and sheet elements 32, which result in stress variations and fatigue life variations.

The large variance that can occur when using mesh independent ACM2 is not acceptable, and offsets the benefits associated with the substantially reduced modelling time. Thus, after conducting modelling of the spot welds 16 of vehicle body 12 using mesh independent ACM2 (step 202), the predicted fatigue life of each of the spot welds 16 of the vehicle body 12 can be reviewed and the various spot welds 16 that did reach 100% of the target fatigue life of 10000 cycles can be identified (step 204). The identified weld spots 16 that did not reach 100% may then be subjected to modelling using mesh dependent ACM2 (step 206), which provides better stiffness, more accurate force and moment results, and better fatigue life predictions. While the modelling time associated with mesh dependent ACM2 is substantially greater than that associated with mesh independent ACM2, it should be understood that the number of weld spots 16 that will be re-modelled using mesh dependent ACM2 will be significantly less than the number of weld spots 16 that were modelled using mesh independent ACM2. Accordingly, the amount of time and costs associated with development of vehicle body 12 having up to 5000 weld spots 16 can be significantly reduced in comparison to only using mesh dependent ACM2.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for determining fatigue life of a plurality of spot welds in a vehicle, comprising:
subjecting a first plurality of coupons that represent welded joints in the vehicle to a plurality of low amplitude cycles to determine a first force (F_{t,n}) associated with a first non-linear characteristic of the spot welds;
subjecting a second plurality of coupons that represent welded joints in the vehicle to a plurality of high amplitude cycles to determine a second force (Fₜ) associated with a second non-linear characteristic of the spot welds;
inputting the first force and the second force into a linear computer aided engineering (CAE) model to generate a third force (F_{e,n}) associated with the first non-linear characteristic of the spot welds and a fourth force (Fₑ) associated with the second non-linear characteristic of the spots welds;
determining a first force factor ((F_{e,n})/(F_{t,n})) associated with the first non-linear characteristic of the spot welds and determining a second force factor ((Fₑ)/(Fₜ)) associated with the second non-linear characteristic of the spot welds;
inputting the first and second force factors into the CAE model to determine internal forces and moments experienced by spot welds;
calculating stresses experienced by the spot welds using the internal forces and moments; and
generating a fatigue life (S-N) curve using the calculated stresses.

2. The method according to claim 1, wherein the CAE model is an Area Contact Model 2 (ACM2).

3. The method according to claim 2, wherein the ACM2 model is mesh dependent.

4. The method according to claim 1, wherein the coupons include lap shear joints and coach peel joints.

5. The method according to claim 1, wherein the first non-linear characteristics is a plasticity of the spot welds at low amplitude cycles.

6. The method according to claim 1, wherein the second non-linear characteristic is a stiffness reduction of the spot welds that can occur due to crack propagation at high amplitude cycles.

7. A method of conducting fatigue analysis of a plurality of spot welds of a vehicle, comprising:
selecting a target fatigue life for the plurality of spot welds;
testing each of the spot welds using a mesh independent linear computer aided engineering (CAE) model;
determining a number of the spot welds that did not reach the target fatigue life; and
testing the number of spot welds that did not reach the target fatigue life using a mesh dependent linear CAE model.

8. The method according to claim 7, wherein the mesh independent linear CAE model is a mesh independent Area Contact Model 2 (ACM2).

9. The method according to claim 7, wherein the mesh dependent linear CAE model is a mesh dependent Area Contact Model 2 (ACM2).
